(19) United States
(12) Patent Application Publication
(10) Pub. No.: US 2019/0006820 A1
(43) Pub. Date: Jan. 3, 2019

(54) VERTICAL CAVITY SURFACE EMITTING LASER AND METHOD FOR MANUFACTURING THE SAME, ELECTRONIC APPARATUS, AND PRINTER

(71) Applicant: Seiko Epson Corporation, Tokyo (JP)

(72) Inventor: Masamitsu MOCHIZUKI, Chino (JP)

(21) Appl. No.: 16/021,309

(22) Filed: Jun. 28, 2018

(30) Foreign Application Priority Data
Jun. 29, 2017 (JP) 2017-127163

(51) Int. Cl. H01S 5/183; H01S 5/042

(52) U.S. Cl. CPC H01S 5/18386; H01S 5/18361; H01S 5/18325; H01S 5/0421

(57) ABSTRACT

A vertical cavity surface emitting laser includes a base and a layered element provided on the base. The layered element includes a first mirror layer, a second mirror layer, and an active layer provided between the first mirror layer and the second mirror layer. The layered element further includes a light exiting section via which light produced in the active layer exits. The light exiting section is an outermost surface of an AlGaInP layer or an AlGaAsP layer.

### BACKGROUND

### 1. Technical Field

The present invention relates to a vertical cavity surface emitting laser and a method for manufacturing the same, an electronic apparatus, and a printer.

### 2. Related Art

A vertical cavity surface emitting laser (VCSEL) is used, for example, as a light source of a laser printer.

For example, JP-A-2012-195510, which describes a vertical cavity surface emitting laser including a lower reflection mirror, an active layer, an upper reflection mirror provided on a substrate, describes that a light exiting area has a surface relief structure having a high reflectance area and a low reflectance area and the outermost surface of the high reflectance area is a GaAs contact layer.

In the vertical cavity surface emitting laser described in JP-A-2012-195510, however, the GaAs contact layer absorbs light produced in the active layer. The optical loss resulting from the absorption causes an increase in laser oscillation threshold and a decrease in laser power.

### SUMMARY

An advantage of some aspects of the invention is to provide a vertical cavity surface emitting laser capable of reducing optical loss resulting from absorption. Another advantage of some aspects of the invention is to provide a method for manufacturing a vertical cavity surface emitting laser capable of reducing optical loss resulting from absorption. Another advantage of some aspects of the invention is to provide an electronic apparatus including the vertical cavity surface emitting laser. Another advantage of some aspects of the invention is to provide a printer including the vertical cavity surface emitting laser.

A vertical cavity surface emitting laser according to an aspect of the invention includes a base, and a layered element provided on the base, in which the layered element includes a first mirror layer, a second mirror layer, and an active layer provided between the first mirror layer and the second mirror layer, the layered element further includes a light exiting section via which light produced in the active layer exits, and the light exiting section is an outermost surface of an AlGaInP layer or an AlGaAsP layer.

In the thus configured vertical cavity surface emitting laser, the bandgap of the light exiting layer, which is an AlGaInP layer or an AlGaAsP layer, is wider than the bandgap of a GaAs layer. The vertical cavity surface emitting laser therefore allows reduction in the optical loss resulting from light absorption that occurs at the outermost layer of the light exiting layer, as compared with a case where the outermost surface of the light exiting layer is a GaAs layer.

In the vertical cavity surface emitting laser according to the aspect of the invention, the first mirror layer may be provided between the base and the second mirror layer, the second mirror layer may include a contact layer connected to an electrode, and the contact layer may be a GaAs layer.

In the thus configured vertical cavity surface emitting laser, the contact resistance between the second mirror layer and the electrode can be reduced.

In the vertical cavity surface emitting laser according to the aspect of the invention, the layered element may include a current narrowing layer that overlaps with the contact layer when viewed in a direction from the first mirror layer to the active layer.

In the thus configured vertical cavity surface emitting laser, the light of a higher-order resonance mode produced in the active layer is absorbed by and lost in the contact layer by a greater amount. Therefore, in the vertical cavity surface emitting laser, out of the resonance modes of the light produced in the active layer, the optical power in a lower order mode can be increased. More specifically, the optical power while keeping the single mode can be increased.

In the vertical cavity surface emitting laser according to the aspect of the invention, the first mirror layer may be provided between the base and the second mirror layer, the second mirror layer may include a layered structure element in which a first layer and a second layer having a refractive index smaller than a refractive index of the first layer, the first layer and the second layer being alternately layered on each other, and a semiconductor layer provided between the layered structure element and a third layer having the outermost surface, and a bandgap of the third layer may be narrower than a bandgap of the semiconductor layer.

In the thus configured vertical cavity surface emitting laser, the barrier (potential barrier) and hence the resistance between the light exiting layer and the semiconductor layer can be reduced.

In the vertical cavity surface emitting laser according to the aspect of the invention, the second mirror layer may include a graded index layer provided between the layered structure element and the semiconductor layer, composition of the graded index layer gradually changes in a direction from the layered structure element toward the semiconductor layer, a sum of half of an optical path length of the graded index layer, an optical path length of the semiconductor layer, and an optical path length of the third layer may be an odd number times of λ/4, where λ is a wavelength of the light produced in the active layer, and an optical path length of the contact layer may be an odd number times of λ/4.

In the thus configured vertical cavity surface emitting laser, the reflectance (reflectance of light produced in the active layer) in the area where the second mirror layer overlaps with the current narrowing layer in the plan view can be reduced. As a result, in the vertical cavity surface emitting laser, out of the resonance modes of the light produced in the active layer, the optical power in lower order modes can be increased. More specifically, the optical power while keeping the single mode can be further increased.

In the vertical cavity surface emitting laser according to the aspect of the invention, the light exiting section may be an outermost surface of the AlGaInP layer, a composition of the AlGaInP layer is represented as a formula (AlₓGa₁₋ₓ)_{1-y}In_{y}P, the x and the y may satisfy y≥0.34x+0.36, 0≤x<1 and y<1.

In the thus configured vertical cavity surface emitting laser, the bandgap of the light exiting layer can be narrower than the bandgap of the semiconductor layer.

In the vertical cavity surface emitting laser according to the aspect of the invention, the x and the y may satisfy y≤0.33x+0.42 and y≤0.61.

The thus configured vertical cavity surface emitting laser prevents the bandgap of the light exiting layer from being too narrow and therefore allows reduction in the optical loss in the light exiting layer and maintains or improves crystal quality of the light exiting layer.

In the vertical cavity surface emitting laser according to the aspect of the invention, the light exiting section may be an outermost surface of the AlGaAsP layer, a composition of the AlGaAsP layer is represented as a formula (AlₓGa₁₋ₓ)_{1-y}As_{y}P, the x and the y may satisfy y≤−3.90x+1.95, 0<x<1 and 0≤y≤0.39.

In the thus configured vertical cavity surface emitting laser, the bandgap of the light exiting layer can be narrower than the bandgap of the semiconductor layer.

In the vertical cavity surface emitting laser according to the aspect of the invention, the x and the y may satisfy y≥−1.39x+0.39.

The thus configured vertical cavity surface emitting laser prevents the bandgap of the light exiting layer from being too narrow and therefore allows reduction in the optical loss in the light exiting layer.

A method for manufacturing a vertical cavity surface emitting laser according to another aspect of the invention includes forming a first mirror layer, an active layer, and a second mirror layer including an AlGaInP layer or an AlGaAsP layer and a contact layer in an order of the first mirror layer, the active layer, and the second mirror layer on a base to form a layered element, forming an electrode connected to the contact layer, and patterning the contact layer after the formation of the electrode in such a way that the AlGaInP layer or the AlGaAsP layer is exposed, in which the layered element includes a light exiting section via which light produced in the active layer exits, and the light exiting section is an outermost surface of the AlGaInP layer or the AlGaAsP layer.

In the thus configured method for manufacturing a vertical cavity surface emitting laser, the outermost surface of the light exiting layer, which is the light exiting section, does not come into contact, for example, with a developer for forming the electrode. The light exiting layer is therefore not eroded with the developer, whereby the thickness of the light exiting layer is maintained, and the outermost surface is allowed to be highly flat.

An electronic apparatus according to another aspect of the invention includes the vertical cavity surface emitting laser according to the aspect of the invention.

The thus configured electronic apparatus can include the vertical cavity surface emitting laser according to the aspect of the invention.

A printer according to another aspect of the invention includes the vertical cavity surface emitting laser according to the aspect of the invention.

The thus configured printer can include the vertical cavity surface emitting laser according to the aspect of the invention.

### BRIEF DESCRIPTION OF THE DRAWINGS

The invention will be described with reference to the accompanying drawings, wherein like numbers reference like elements.

FIG. 1 is a cross-sectional view diagrammatically showing a vertical cavity surface emitting laser according to an embodiment of the invention.

FIG. 2 is a cross-sectional view diagrammatically showing the vertical cavity surface emitting laser according to the present embodiment.

FIG. 3 is a graph showing the relationship between x and y of (AlₓGa_{1-X})_{1-y}In_{y}P.

FIG. 4 is a flowchart for describing a method for manufacturing the vertical cavity surface emitting laser according to the present embodiment.

FIG. 5 is a cross-sectional view diagrammatically showing one of the steps of manufacturing the vertical cavity surface emitting laser according to the present embodiment.

FIG. 6 is a cross-sectional view diagrammatically showing one of the steps of manufacturing the vertical cavity surface emitting laser according to the present embodiment.

FIG. 7 is a cross-sectional view diagrammatically showing one of the steps of manufacturing the vertical cavity surface emitting laser according to the present embodiment.

FIG. 8 is a cross-sectional view diagrammatically showing one of the steps of manufacturing the vertical cavity surface emitting laser according to the present embodiment.

FIG. 9 is a graph showing the relationship between x and y of (AlₓGa₁₋ₓ)_{1-y}As_{y}P.

FIG. 10 is a perspective view diagrammatically showing a biological information acquiring apparatus according to the present embodiment.

FIG. 11 is a plan view diagrammatically showing the biological information acquiring apparatus according to the present embodiment.

FIG. 12 is another plan view diagrammatically showing the biological information acquiring apparatus according to the present embodiment.

FIG. 13 is a functional block diagram of the biological information acquiring apparatus according to the present embodiment.

FIG. 14 is another functional block diagram of the biological information acquiring apparatus according to the present embodiment.

FIG. 15 diagrammatically shows a printer according to the present embodiment.

FIG. 16 diagrammatically shows a light exposure unit provided in the printer according to the present embodiment.

### DESCRIPTION OF EXEMPLARY EMBODIMENTS

A preferable embodiment of the invention will be described below in detail with reference to the drawings. It is not intended that the embodiment described below unduly limits the contents of the invention set forth in the appended claims. Further, all configurations described below are not necessarily essential configuration requirements of the invention.

### 1. Vertical Cavity Surface Emitting Laser

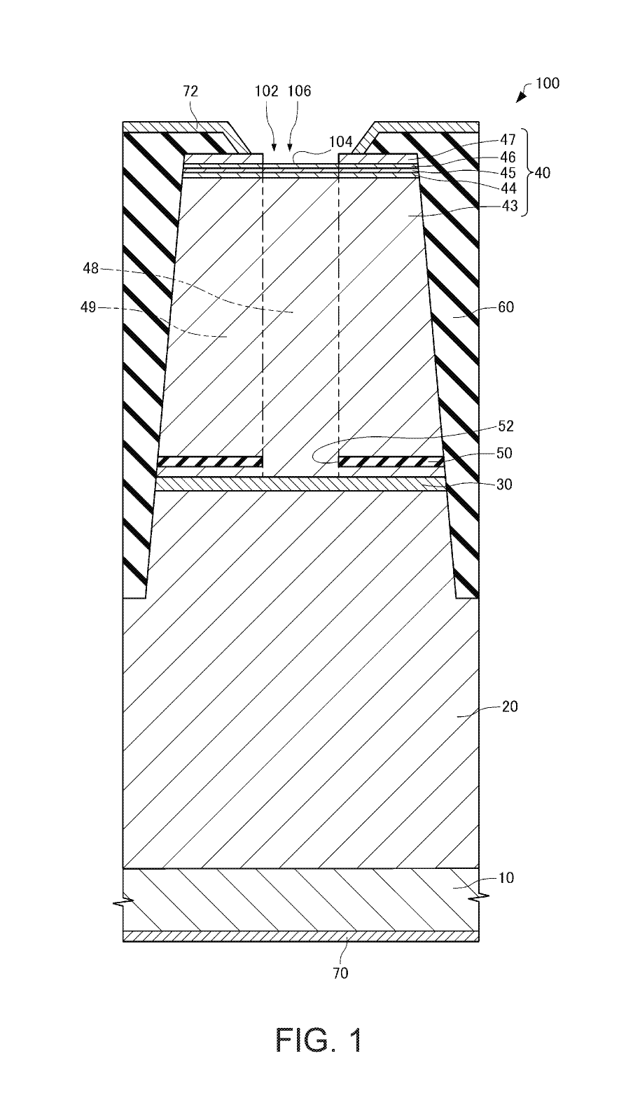

A vertical cavity surface emitting laser according to the present embodiment will first be described with reference to the drawings. FIG. 1 is a cross-sectional view diagrammatically showing a vertical cavity surface emitting laser 100 according to the present embodiment.

The vertical cavity surface emitting laser 100 includes a base 10 and a layered element 102 provided on the base 10, as shown in FIG. 1. The layered element 102 includes a first mirror layer 20, an active layer 30, a second mirror layer 40, and a current narrowing layer 50. The vertical cavity surface emitting laser 100 further includes an insulating layer 60, a first electrode 70, and a second electrode 72. The following description will be made of the vertical cavity surface emitting laser 100 that outputs red light (light having wavelength longer than or equal to 660 nm but shorter than or equal to 700 nm, for example) by way of example.

The base 10 is, for example, a first-conductivity-type (n-type, for example) GaAs substrate.

The first mirror layer 20 is provided on the base 10. The first mirror layer 20 is provided between the base 10 and the second mirror layer 40. The first mirror layer 20 is a first-conductivity-type semiconductor layer. The first mirror layer 20 has a layered structure element in which a high-refractive-index layer and a low-refractive-index layer having a refractive index smaller than that of the high-refractive-index layer are alternately layered on each other. The first mirror layer 20 is a distributed Bragg reflection (DBR) mirror. The high-refractive-index layers are each, for example, an Al_{0.5}Ga_{0.5}As layer. The low-refractive-index layers are each, for example, an Al_{0.9}Ga_{0.1}As layer. The number of layered high-refractive-index layers and low-refractive-index layers (number of pairs) is, for example, greater than or equal to 40 but smaller than or equal to 80, preferably, 60.

The active layer 30 is provided on the first mirror layer 20. The active layer 30 is provided between the first mirror layer 20 and the second mirror layer 40. The active layer 30 can emit light when current is injected thereinto.

The active layer 30 has, for example, a multiple quantum well (MQW) structure in which three quantum well structures each formed of an i-type GaInP layer (well layer) and an i-type AlGaInP layer (barrier layer) are layered on each other. The active layer 30 may further include a first confinement layer and a second confinement layer that sandwich the multiple quantum well structure. The first and second confinement layers are each, for example, an i-type AlGaInP layer.

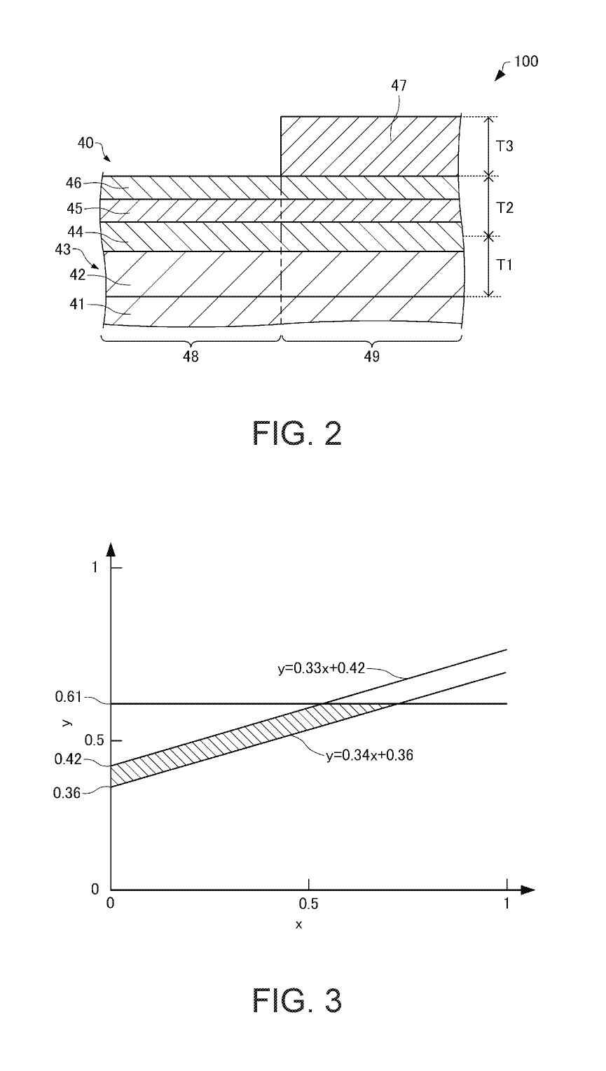

The second mirror layer 40 is provided on the active layer 30. The second mirror layer 40 is a second-conductivity-type (p-type, for example) semiconductor layer. The layered element 102 includes a light exiting section 104, via which the light produced in the active layer 30 exits. In the example shown in FIG. 1, the second mirror layer 40 includes the light exiting section 104. FIG. 2 is a cross-sectional view diagrammatically showing the vicinity of the light exiting section 104 of the vertical cavity surface emitting laser 100. In FIG. 2, the insulating layer 60 and the second electrode 72 are omitted for convenience.

The second mirror layer 40 includes a layered structure element 43 including high-refractive-index layers (first layers) 41 and low-refractive-index layers (second layers) 42, a graded index layer 44, a semiconductor layer 45, a light exiting layer (third layer) 46, and a contact layer 47, as shown in FIG. 2.

The layered structure element 43 is provided on the active layer 30. The layered structure element 43 has a layered structure in which the high-refractive-index layers 41 and the low-refractive-index layers 42, which each have a refractive index lower than that of the high-refractive-index layers 41, are alternately layered. The second mirror layer 40 is a distributed Bragg reflection (DBR) mirror. The high-refractive-index layers 41 are each, for example, an Al_{0.5}Ga_{0.5}As layer. The low-refractive-index layers 42 are each, for example, an Al_{0.9}Ga_{0.1}As layer. The number of layered high-refractive-index layers 41 and low-refractive-index layers 42 (number of pairs) is, for example, greater than or equal to 20 but smaller than or equal to 60, preferably, greater than or equal to 30 but smaller than or equal to 50. In the example shown in FIG. 2, the top layer of the layered structure element 43 is the low-refractive-index layer 42.

The graded index layer 44 is provided on the layered structure element 43. The graded index layer 44 is a layer having a composition that gradually changes in the direction from the layered structure element 43 toward the semiconductor layer 45 (upward). Specifically, in a case where the low-refractive-index layers 42 of the layered structure element 43 are each an Al_{0.9}Ga_{0.1}As layer and the semiconductor layer 45 is made of Al_{0.5}Ga_{0.5}As, the graded index layer 44 is a layer having composition that gradually changes upward from Al_{0.9}Ga_{0.1}As to Al_{0.5}Ga_{0.5}As. In the graded index layer 44, for example, the composition of the lower surface is the same as the composition of the low-refractive-index layers 42 of the layered structure element 43, and the composition of the upper surface is the same as the composition of the semiconductor layer 45. The thickness of the graded index layer 44 is, for example, greater than or equal to 10 nm but smaller than or equal to 25 nm. Providing the graded index layer 44 allows reduction in resistance of the second mirror layer 40.

The semiconductor layer 45 is provided on the graded index layer 44. The semiconductor layer 45 is provided between the layered structure element 43 and the light exiting layer 46. The semiconductor layer 45, for example, has the same composition as that of the high-refractive-index layers 41 of the layered structure element 43. The semiconductor layer 45 is, for example, a Al_{0.5}Ga_{0.5}As layer. Providing the semiconductor layer 45 allows the light exiting layer 46 to be provided on the layer having a stable composition.

The light exiting layer 46 is provided on the semiconductor layer 45. The light exiting section 104 is the outermost surface of the light exiting layer 46. Specifically, the light exiting section 104 is an area of the outermost (upper) surface of the light exiting layer 46 and the area that is not in contact with the contact layer 47. The light exiting section 104 has, for example, a circular plan shape (circular shape when viewed in layered direction).

The light exiting layer 46 is an AlGaInP layer. The composition of the light exiting layer 46 is (AlₓGa₁₋ₓ)_{1-y}In_{y}P. The variables x and y in the composition ((AlₓGa₁₋ₓ)_{1-y}In_{y}P) of the light exiting layer 46 satisfy, for example, the following Expression (1), preferably, further satisfy the following Expression (2).

y≥0.34x+0.36, 0≤x<1 and y<1 (1)

y≤0.33x+0.42 and y≤0.61 (2)

When Expressions (1) and (2) are satisfied, x and y of the composition of the light exiting layer 46 are allowed to fall within the hatched range, as shown in FIG. 3, where the horizontal axis represents x and the vertical axis represents y. As indicated by Expressions and shown in FIG. 3, x may be zero. That is, the light exiting layer 46, which is an AlGaInP layer, may contain no Al.

The bandgap of the light exiting layer 46 is wider than the bandgap of the contact layer 47. The bandgap of the light exiting layer 46 is narrower than the bandgap of the semiconductor layer 45. The thickness of the light exiting layer 46 is, for example, greater than or equal to 20 nm but smaller than or equal to 60 nm.

The contact layer 47 is so provided on the light exiting layer 46 as not to cover the light exiting section 104. The contact layer 47 is connected to the second electrode 72. The thickness of the contact layer 47 is, for example, greater than or equal to 30 nm but smaller than or equal to 70 nm. The contact layer 47 is a GaAs layer.

Let λ be the wavelength of the light produced in the active layer 30, and the sum of the optical path length of the top low-refractive-index layer 42 of the layered structure element 43 and half the optical path length of the graded index layer 44 is an odd number times of λ/4. The sum of half the optical path length of the graded index layer 44, the optical path length of the semiconductor layer 45, and the optical path length of the light exiting layer 46 is an odd number times of λ/4. The optical path length of the contact layer 47 is an odd number times of λ/4. The total thickness T1 of the thickness of the top low-refractive-index layer 42 of the layered structure element 43 and half the thickness of the graded index layer 44 is an odd number times of λ/(4n), as shown in FIG. 2. The total thickness T2 of half the thickness of the graded index layer 44, the thickness of the semiconductor layer 45, and the thickness of the light exiting layer 46 is an odd number times of λ/(4n). The thickness T3 of the contact layer 47 is an odd number times of λ/(4n). The second mirror layer 40 can therefore have a high-reflectance area 48 and a low-reflectance area 49.

Although not shown, a graded index layer may be provided between the top low-refractive-index layer 42 of the layered structure element 43 and the high-refractive-index layer 41 located below (immediately below) the top low-refractive-index layer 42. The graded index layer may be a layer having composition that gradually changes from Al_{0.5}Ga_{0.5}As to Al_{0.9}Ga_{0.1}As in the direction from the high-refractive-index layer 41 toward the low-refractive-index layer 42. The sum of half the thickness of the graded index layer, the thickness of the top low-refractive-index layer 42 of the layered structure element 43, and half the thickness of the graded index layer 44 may be an odd number times of λ/(4n).

The high-reflectance area 48 is an area that does not overlap with the contact layer 47 (area that overlaps with light exiting section 104) in a plan view (when viewed in layered direction). The upper surface of the high-reflectance area 48 is the light exiting section 104. The low-reflectance area 49 is an area that overlaps with the contact layer 47 in the plan view. The reflectance at which the low-reflectance area 49 reflects the light produced in the active layer 30 is lower than the reflectance at which the high-reflectance area 48 reflects the light produced in the active layer 30. The light produced in the active layer 30 primarily undergoes multiple reflection in the high-reflectance area 48.

In λ/(4n) described above, by which the thicknesses T1, T2, and T3 are expressed, X represents the wavelength of the light produced in the active layer 30. In the expression of each of the thicknesses T1 and T2, n represents the average refractive index of the layer having the thickness (average refractive index in consideration of proportions of optical path lengths). In the expression of the thickness T3, n represents the refractive index of the contact layer 47.

It is, however, noted that in a case where the thicknesses T1, T2, and T3 each, for example, fall within ±10% of the set value (odd multiple of λ/(4n)), a sufficient difference in the reflectance between the high-reflectance area 48 and the low-reflectance area 49 can be provided.

The second mirror layer 40, the active layer 30, and part of the first mirror layer 20 form a columnar section 106, as shown in FIG. 1. In the example shown in FIG. 1, the side surface of the columnar section 106 inclines with respect to the upper surface of the base 10.

The second mirror layer 40, the active layer 30, and the first mirror layer 20 form a vertical resonator and pin diode. When voltage in the forward direction of the pin diode is applied between the electrodes 70 and 72, electrons and holes are recombined with each other in the active layer 30, resulting in light emission. The light produced in the active layer 30 travels back and forth between the first mirror layer 20 and the second mirror layer 40 (undergoes multiple reflection), resulting in stimulated emission and hence intensity amplification. Once the optical gain exceeds the optical loss, laser oscillation occurs, and a laser beam exits out of the light exiting section 104 in the layered direction.

The current narrowing layer 50 is so provided as to be sandwiched between layers that form the layered structure element 43 of the second mirror layer 40 (high-refractive-index layers 41, for example). The current narrowing layer 50 is formed, for example, by oxidizing at least one of the layers that form the second mirror layer 40. The high-reflectance area 48 does not overlap with the current narrowing layer 50 in the plan view. The low-reflectance area 49 overlaps with the current narrowing layer 50 in the plan view. The current narrowing layer 50 overlaps with the contact layer 47 in the plan view.

The current narrowing layer 50 is an insulating layer having an opening 52 formed therein. The opening 52 has, for example, a circular plan shape. The current narrowing layer 50 is formed, for example, in a ring-like shape. In the example shown in FIG. 1, the width of the light exiting section 104 (size thereof in direction perpendicular to layered direction) is equal to the width of the opening 52. In the plan view, the diameter of the light exiting section 104 is equal to the diameter of the opening 52, and the light exiting section 104 and the opening 52 may exactly coincide with each other in the plan view.

The insulating layer 60 is provided around the columnar section 106 and on the contact layer 47. The insulating layer 60 is, for example, a polyimide layer or a silicon oxide layer.

The first electrode 70 is provided below the base 10. The first electrode 70 is in ohmic contact with the base 10. The first electrode 70 is electrically connected to the first mirror layer 20 via the base 10. The first electrode 70 is formed, for example, by layering a Cr layer, an AuGe layer, an Ni layer, and an Au layer in the presented order from the side facing the base 10. The first electrode 70 is one of the electrodes for injecting current into the active layer 30.

The second electrode 72 is provided on the contact layer 47 and the insulating layer 60. The second electrode 72 is in ohmic contact with the contact layer 47. The second electrode 70 is electrically connected to the second mirror layer 40. The second electrode 72 is formed, for example, by layering a Cr layer, a Pt layer, a Ti layer, a Pt layer, and an Au layer in the presented order from the side facing the contact layer 47. The second electrode 72 is the other one of the electrodes for injecting current into the active layer 30.

The vertical cavity surface emitting laser 100 has, for example, the following features.

In the vertical cavity surface emitting laser 100, the layered element 102 includes the light exiting section 104, via which the light produced in the active layer 30 exits, and the light exiting section 104 an area of is the outermost surface of the light exiting layer 46, which is an AlGaInP layer. The bandgap of the light exiting layer 46 is therefore wider than the bandgap of a GaAs layer. The vertical cavity surface emitting laser 100 therefore allows reduction in the optical loss resulting from the light absorption that occurs at the outermost layer of the light exiting layer 46, as compared with a case where the outermost surface of the light exiting layer is a GaAs layer. As a result, the vertical cavity surface emitting laser 100 allows a decrease in the laser oscillation threshold (increase in efficiency) and an increase in optical power.

In the vertical cavity surface emitting laser 100, the second mirror layer 40 has the contact layer 47, which is connected to the second electrode 72, and the contact layer 47 is a GaAs layer. Therefore, in the vertical cavity surface emitting laser 100, the contact resistance between the second mirror layer 40 and the second electrode 72 can be reduced.

In the vertical cavity surface emitting laser 100, the layered element 102 includes the current narrowing layer 50, which overlaps with the contact layer 47 in the plan view. Among the resonance modes of the light produced in the active layer 30, a photoelectric magnetic field permeates greater amount into the area where the active layer 30 overlaps with the current narrowing layer 50 in the plan view (low-reflectance area 49) in a higher order mode. Therefore, in vertical cavity surface emitting laser 100, among the resonance modes of the light produced in the active layer 30, greater amount of the light is absorbed and lost in the contact layer 47 in a higher order mode. Therefore, the optical power in a lower order mode among the resonance modes of the light produced in the vertical cavity surface emitting laser 100 can be increased. More specifically, the optical power while keeping the single mode can be increased. Further, in the vertical cavity surface emitting laser 100, since optical loss occurs in high order modes, a change in a far field pattern (FFP) (change in radiation pattern resulting from change in mode) can be suppressed.

The vertical cavity surface emitting laser 100 includes the layered structure element 43 and the semiconductor layer 45, which is provided between the layered structure element 43 and the light exiting layer 46, and the bandgap of the light exiting layer 46 is narrower than the bandgap of the semiconductor layer 45. Therefore, in the vertical cavity surface emitting laser 100, the barrier (potential barrier) and hence the resistance between the light exiting layer 46 and the semiconductor layer 45 can be reduced.

In the vertical cavity surface emitting laser 100, the sum of half the optical path length of the graded index layer 44, the optical path length of the semiconductor layer 45, and the optical path length of the light exiting layer 46 is an odd number times of λ/4, where λ represents the wavelength of the light produced in the active layer 30. The optical path length of the contact layer 47 is an odd number times of λ/4. Therefore, in the vertical cavity surface emitting laser 100, the reflectance (reflectance of light produced in the active layer 30) in the area where the second mirror layer 40 overlaps with the current narrowing layer 50 in the plan view (low-reflectance area 49) can be reduced. As a result, in the vertical cavity surface emitting laser 100, the optical power in lower order modes among the resonance modes of the light produced in the active layer can be increased. More specifically, the optical power while keeping the single mode can be further increased.

In the vertical cavity surface emitting laser 100, the composition of the light exiting layer 46 is represented as a formula (AlₓGa₁₋ₓ)_{1-y} In_{y}P, wherein x and y satisfy Expression (1). Therefore, in the vertical cavity surface emitting laser 100, the bandgap of the light exiting layer 46 can be narrower than the bandgap of the semiconductor layer 45.

Further, in the vertical cavity surface emitting laser 100, x and y satisfy Expression (2). When the expression y≤0.33x+0.42 is satisfied, it is prevented that the bandgap of the light exiting layer 46 from being too narrow, and reduction in the optical loss in the light exiting layer 46 is performed in the vertical cavity surface emitting laser 100. Further, when the expression y≤0.61 is satisfied, it is possible to maintain or improve crystal quality of the light exiting layer 46 in the vertical cavity surface emitting laser 100.

In the example shown in FIG. 1, the width of the opening 52 is equal to the width of the light exiting section 104. Instead, the width of the opening 52 may be smaller or greater than the width of the light exiting section 104. It is, however noted that the configuration in which the width of the opening 52 is smaller than the width of the light exiting section 104 results in a decrease in the optical loss in high order modes. The high order modes are therefore more likely to occur. In the case where the width of the opening 52 is greater than the width of the light exiting section 104, the optical loss that occurs in low order modes also increases, but the light emitting area can be enlarged. The optical power of the vertical cavity surface emitting laser 100 can therefore be increased.

### 2. Method for Manufacturing Vertical Cavity Surface Emitting Laser

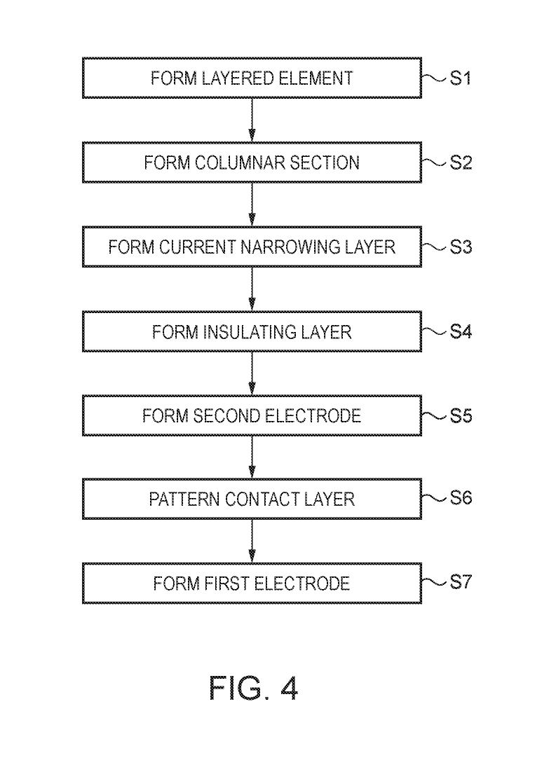

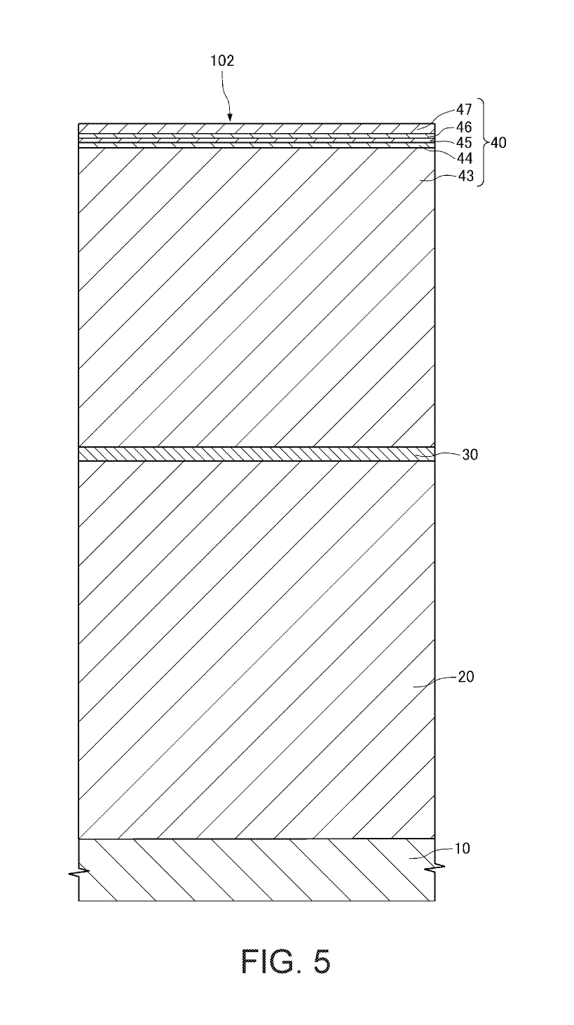

A method for manufacturing the vertical cavity surface emitting laser according to the present embodiment will next be described with reference to the drawings. FIG. 4 is a flowchart for describing the method for manufacturing the vertical cavity surface emitting laser 100 according to the present embodiment. FIGS. 5 to 8 are cross-sectional views diagrammatically showing the steps of manufacturing the vertical cavity surface emitting laser 100 according to the present embodiment.

The first mirror layer 20, the active layer 30, and the second mirror layer 40 are formed in the presented order on the base 10 to form the layered element 102 (step S1), as shown in FIG. 5. The second mirror layer 40 is formed by forming the layered structure element 43, the graded index layer 44, the semiconductor layer 45, the light exiting layer 46, and the contact layer 47 in the presented order. The layers of the layered element 102 are each epitaxially grown, for example, by a metal organic chemical vapor deposition (MOCVD) method or a molecular beam epitaxy (MBE) method.

In general, an AlGaInP layer is formed at a temperature (about 700° C., for example) higher than the temperature at which an AlGaAs layer is formed. The reason for this is to suppress creation of a superlattice, activate a dopant (Mg or Zn, for example), increase the efficiency of decomposition of PH₃ (phosphine) contained in a gas used in the film formation, and achieve other purposes. In the vertical cavity surface emitting laser 100, however, the light exiting layer 46, which is an AlGaInP layer, is very thin, for example, smaller than λ/(4n), whereby the light exiting layer 46 can be formed with no change of the temperature but at the same temperature at which the layered structure element 43, which is formed of AlGaAs layers, and other components are formed.

Further, the contact layer 47, which is a GaAs layer, is typically formed by using tert-butyl alcohol (TBA) as the material of arsenic (As) to automatically dope carbon (C) contained in the TBA. A highly doped contact layer 47 can thus be formed. In the case where TBA is used as the material of As, the contact layer 47 is grown at a low temperature whose range is about 550 to 560° C. In the vertical cavity surface emitting laser 100, however, since the contact layer 47, which is a GaAs layer, has a small thickness, for example, λ/(4n), the contact layer 47 can be formed by intentionally adding a dopant (Mg or Zn, for example) with no change of the temperature but at the same temperature at which the layered structure element 43, which is formed of AlGaAs layers, and other components are formed.

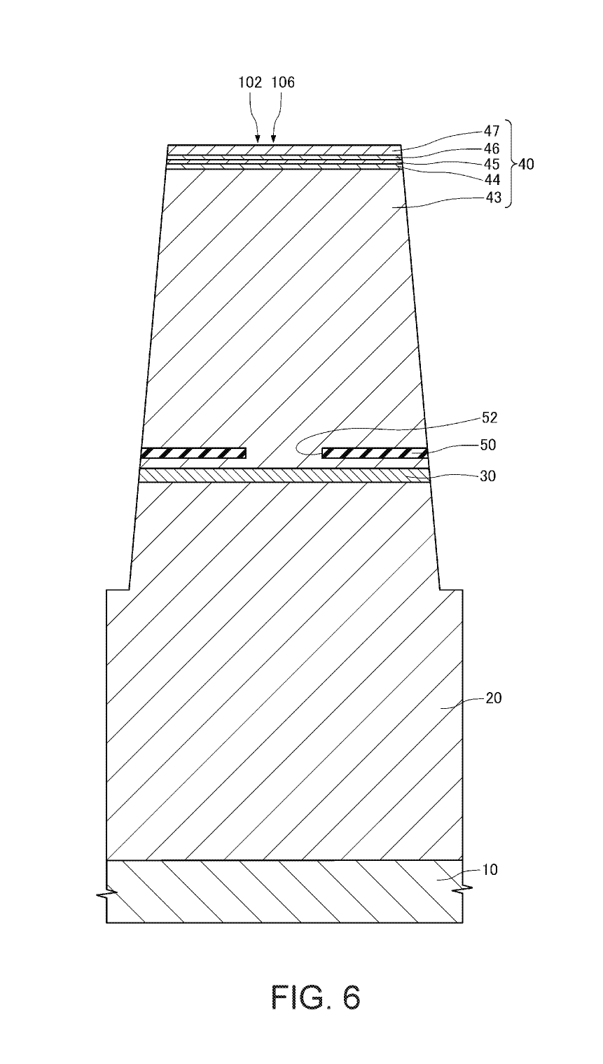

The layered element 102 is patterned to form the columnar section 106 (step S2), as shown in FIG. 6. The patterning is performed, for example, by using photolithography and etching.

Thereafter, for example, one of the layers of the layered structure element 43 is oxidized to form the current narrowing layer 50 (step S3). The one layer is, for example, an AlₓGa₁₋ₓAs (x≥0.95) layer. For example, the current narrowing layer 50 is formed by placing the base 10 on which the layered element 102 has been formed in a vapor atmosphere at about 400° C. to oxidize the AlₓGa₁₋ₓAs (x≥0.95) layer inward from the side surface thereof.

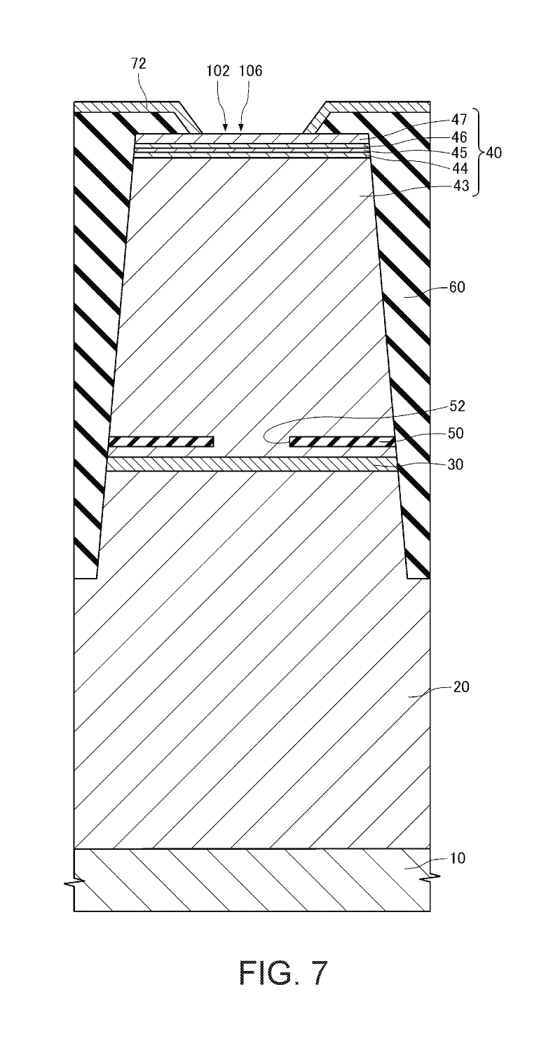

The insulating layer 60 is formed around the columnar section 106 and on the contact layer 47 (step S4), as shown in FIG. 7. The insulating layer 60 is formed, for example, by spin coating and patterning based on photolithography and etching.

The second electrode 72, which will be connected to the contact layer 47, is then formed (step S5). The second electrode 72 is formed on the insulating layer 60. The second electrode 72 is formed, for example, by using a vacuum evaporation method.

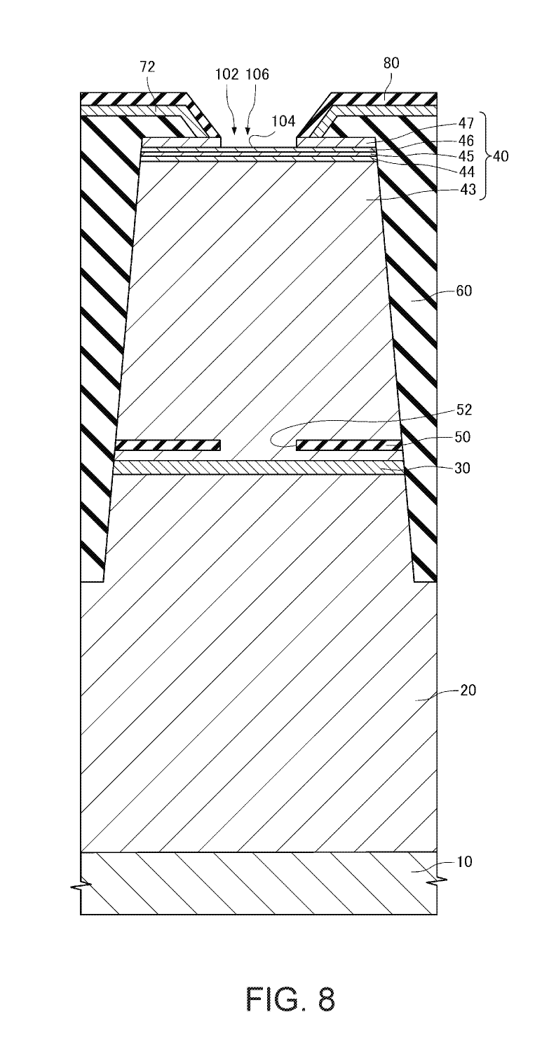

The contact layer 47 is so patterned as to expose the light exiting layer 46 (step S6), as shown in FIG. 8. The patterning of the contact layer 47 is performed by forming a resist layer 80 having a predetermined shape on the contact layer 47 and the second electrode 72 in a photolithography process and performing etching using, for example, ammonia-hydrogen peroxide mixture (mixture of ammonia and hydrogen peroxide) with the resist layer 80 used as a mask. The resist layer 80 is then removed.

The first electrode 70 is formed below the base 10 (step S7), as shown in FIG. 1. The first electrode 70 is formed, for example, by using a vacuum evaporation method. The first electrode 70 and the second electrode 72 are then alloyed, for example, by a heat treatment.

The vertical cavity surface emitting laser 100 can be manufactured by carrying out the steps described above.

In the method for manufacturing the vertical cavity surface emitting laser 100, after the second electrode 72 is formed (step S5), the contact layer 47 is so patterned as to expose the light exiting layer 46 (step S6). Therefore, in the method for manufacturing the vertical cavity surface emitting laser 100, the upper surface of the light exiting layer 46, which is the light exiting section 104, does not come into contact, for example, with a developer for forming the second electrode 72. The light exiting layer 46 is therefore not eroded with the developer, whereby the upper surface of the light exiting layer 46 is allowed to be highly flat. Further, a situation in which the thickness of the light exiting layer 46 deviates from a desired value can be avoided. As a result, the method for manufacturing the vertical cavity surface emitting laser 100 allows the high-reflectance area 48 to have stable reflectance, whereby the yield of the vertical cavity surface emitting laser 100 can be improved.

### 3. Variation of Vertical Cavity Surface Emitting Laser

A vertical cavity surface emitting laser according to a variation of the present embodiment will next be described. The description of the vertical cavity surface emitting laser according to the variation of the present embodiment will be made of points different from those of the vertical cavity surface emitting laser 100 according to the present embodiment described above, and the same points will not be described.

The vertical cavity surface emitting laser according to the variation of the present embodiment differs from the vertical cavity surface emitting laser 100 described above in that the light exiting layer 46 is an AlGaAsP layer. In the vertical cavity surface emitting laser according to the variation of the present embodiment, the composition of the light exiting layer 46 is (AlₓGa₁₋ₓ)_{1-y}As_{y}P. The variables x and y of the composition of the light exiting layer 46 ((AlₓGa₁₋ₓ)_{1-y}As_{y}P) satisfy, for example, the following Expression (3), preferably, further satisfy the following Expression (4).

y≤−3.90x+1.95, 0<x<1 and 0≤y≤0.39 (3)

y≥−1.39x+0.39 (4)

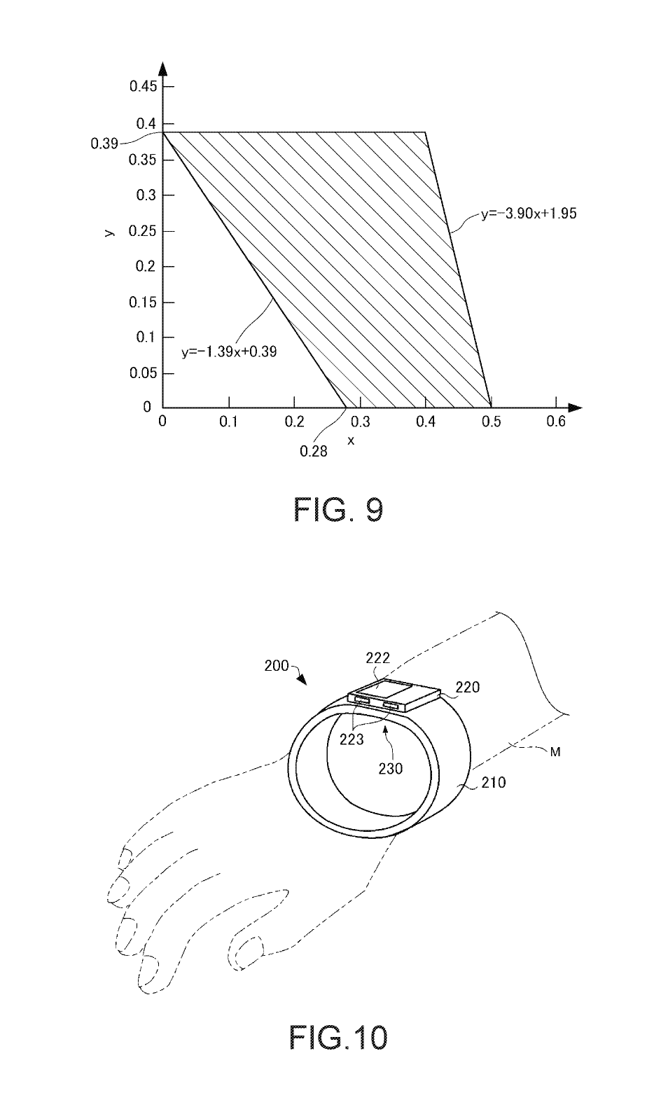

When Expressions (3) and (4) are satisfied, x and y of the composition of the light exiting layer 46 are allowed to fall within the hatched range, as shown in FIG. 9, where the horizontal axis represents x and the vertical axis represents y. As indicated by Expressions and shown in FIG. 9, y may be zero. That is, the light exiting layer 46, which is an AlGaAsP layer, may contain no As.

The vertical cavity surface emitting laser according to the variation of the present embodiment can provide the same effects as those provided by the vertical cavity surface emitting laser 100 described above.

In the vertical cavity surface emitting laser according to the variation of the present embodiment, the composition of the light exiting layer 46 is (AlₓGa₁₋ₓ)_{1-y}As_{y}P, and x and y satisfy Expression (3). Therefore, in the vertical cavity surface emitting laser according to the variation of the present embodiment, the bandgap of the light exiting layer 46 can be narrower than the bandgap of the semiconductor layer 45.

Further, in the vertical cavity surface emitting laser according to the variation of the present embodiment, x and y satisfy Expression (4). The vertical cavity surface emitting laser according to the variation of the present embodiment therefore prevents the bandgap of the light exiting layer 46 from being too narrow and allows reduction in the optical loss in the light exiting layer 46.

### 4. Electronic Apparatus

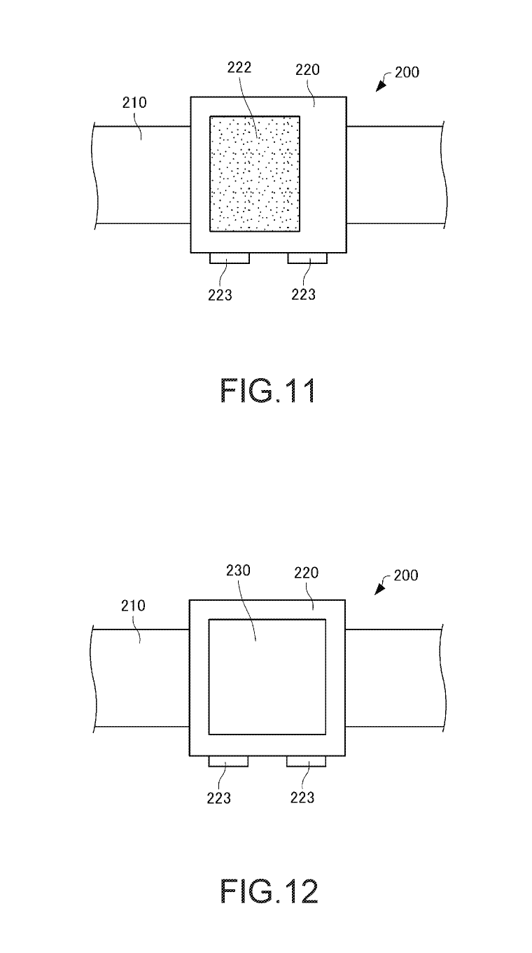

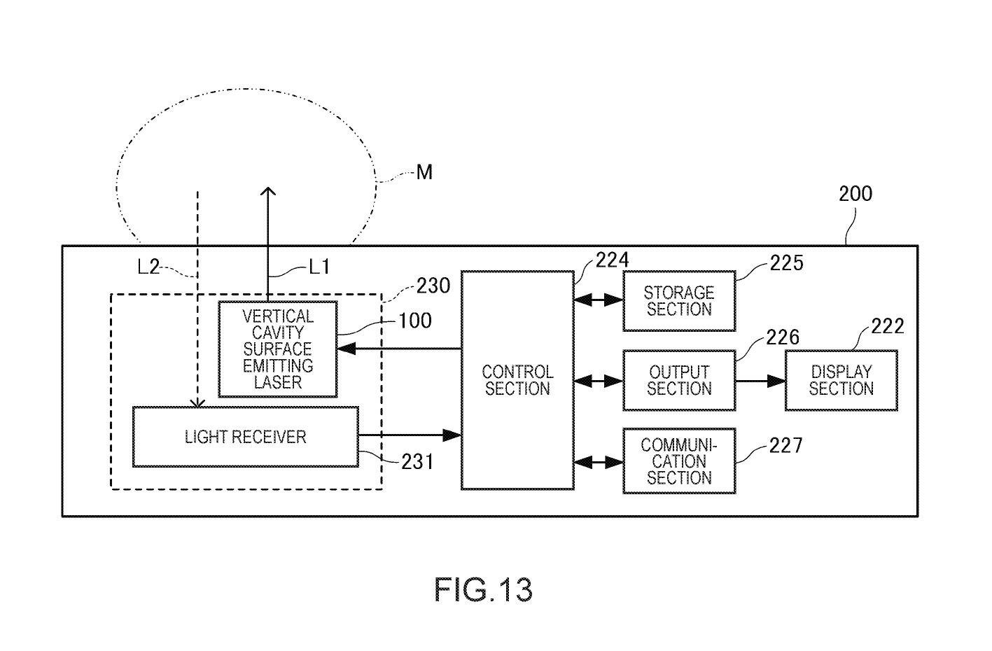

An electronic apparatus according to the present embodiment will next be described with reference to the drawings. The following description will be made of a biological information acquiring apparatus as an example of the electronic apparatus according to the present embodiment. FIG. 10 is a perspective view diagrammatically showing a biological information acquiring apparatus 200 according to the present embodiment. FIGS. 11 and 12 are plan views diagrammatically showing the biological information acquiring apparatus 200 according to the present embodiment. FIG. 13 is a functional block diagram of the biological information acquiring apparatus 200 according to the present embodiment.

FIG. 11 is a plan view of the biological information acquiring apparatus 200 and shows the side (front side) opposite the side facing a human body M. FIG. 12 is a plan view of the biological information acquiring apparatus 200 and shows the side (rear side) facing the human body M.

The biological information acquiring apparatus according to the embodiment of the invention includes one of the vertical cavity surface emitting lasers according to the embodiment of the invention. The following description will be made of the biological information acquiring apparatus 200 including the vertical cavity surface emitting laser 100 described above as one of the vertical cavity surface emitting lasers according to the embodiment of the invention.

The biological information acquiring apparatus 200 is a portable information terminal worn around a wrist of the human body M. The biological information acquiring apparatus 200 can noninvasively and optically detect the content of a specific component in the blood in a blood vessel, for example, glucose to identify the blood sugar level, detect light that has not been absorbed by hemoglobin but has returned to identify arterial blood oxygen saturation (SpO₂), and detect a pulsation-induced change in the amount of light absorbed by hemoglobin to identify the pulse.

The biological information acquiring apparatus 200 includes an annular belt 210, which can be worn around a wrist, and a main body case 220, which is attached to the belt 210, as shown in FIGS. 10 to 12.

The main body case 220 incorporates a display section 222 and a sensor section 230. The display section 222 is provided in the main body case 220 and on the side opposite the human body M. The sensor section 230 is provided on the side facing the human body M. The sensor section 230 is so provided, for example, as to come into contact with the human body M. The main body case 220 further incorporates operation buttons 223, a control section 224 and other circuit systems, a battery as a power source, and other components.

The biological information acquiring apparatus 200 includes the display section 222, the control section 224, a storage section 225, an output section 226, a communication section 227, and the sensor section 230, as shown in FIG. 13.

The sensor section 230 includes the vertical cavity surface emitting laser 100 and a light receiver 231. The vertical cavity surface emitting laser 100 and the light receiver 231 are each electrically connected to the control section 224. The control section 224 drives the vertical cavity surface emitting laser 100 to emit light L1. The light L1 propagates through the human body M and is scattered and absorbed. The sensor section 230 is configured to be capable of receiving part of the light L1 scattered in the human body M in the form of light L2 with the light receiver 231. The light receiver 231 is formed, for example, of a photodiode.

The control section 224 can cause the storage section 225 to store information on the light L2 received with the light receiver 231. The control section 224 then causes the output section 226 to process the information on the light L2. The output section 226 converts the information on the light L2 into information on the content of a specific component in the blood, outputs the content information, converts the information on the light L2 into the pulse, and outputs information on the pulse. The control section 224 can cause the display section 222 to display the information on the specific component in the blood and the information on the pulse. The biological information acquiring apparatus 200 can, for example, transmit these pieces of information via the communication section 227 to another information processing apparatus.

The control section 224 can receive a program and other pieces of information from the other information processing apparatus via the communication section 227 and cause the storage section 225 to store the program and other pieces of information. The communication section 227 may be a wired communicator connected to the other information processing apparatus via a wire or a wireless communicator compliant, for example, with Bluetooth (registered trademark). The control section 224 may not only cause the display section 222 to display acquired information on the blood vessel and blood but cause the display section 222 to display a program and other pieces of information stored in the storage section 225 in advance and the current time and other pieces of information. The storage section 225 may be a removable memory.

The function of the display section 222 can be achieved, for example, by an LCD (liquid crystal display) and or an EL display (electroluminescence display). The functions of the control section 224 and the output section 226 can be achieved, for example, by a variety of processors (such as CPU and DSP) and other types of hardware or programs. The function of the storage section 225 can be achieved, for example, by a hard disk drive or a RAM (random access memory).

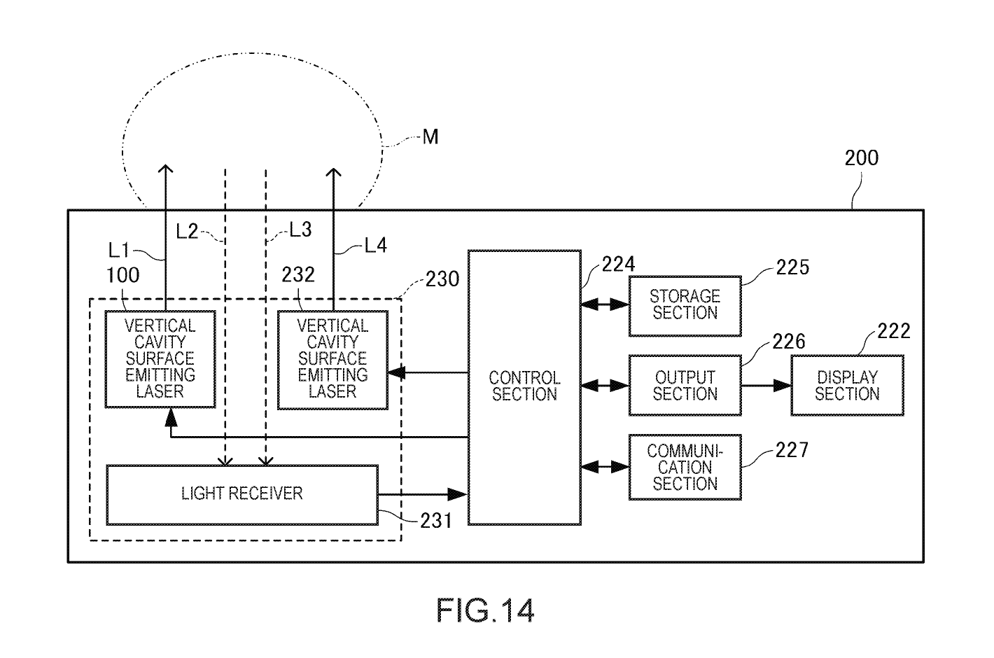

In a case where the biological information acquiring apparatus 200 is an SpO₂ measuring apparatus, the sensor section 230 includes a vertical cavity surface emitting laser 232 as well as the vertical cavity surface emitting laser 100, as shown in FIG. 14. The vertical cavity surface emitting laser 100 emits the red light L1, and the vertical cavity surface emitting laser 232 emits infrared light L4. The light receiver 231 receives part of the light L1 scattered in the human body M in the form of the light L2 and receives part of the light L4 scattered in the human body M in the form of light L3. The output section 226 converts the intensity ratio between the light L2 and the light L3 into SpO₂ and outputs information on the SpO₂. The control section 224 can cause the display section 222 to display the information on SpO₂.

Regarding the amount of red light absorbed by hemoglobin, the amount of red light absorbed by in-blood oxidized hemoglobin is greater than the amount of red light absorbed by in-blood reduced hemoglobin. On the other hand, the amount of red light absorbed by in-blood reduced hemoglobin is smaller than the amount of red light absorbed by in-blood oxidized hemoglobin. The biological information acquiring apparatus 200 can therefore calculate an SpO₂ value from the ratio between the light L2 and the light L4 in terms of pulsation-induced change in the amount of absorption.

In the example shown FIGS. 10 to 14, the biological information acquiring apparatus 200 has been described as a wristwatch-shaped apparatus worn around a wrist of the human body M. The biological information acquiring apparatus according to the embodiment of the invention may instead be an upper-arm-type apparatus worn around an upper arm, an earlobe-type apparatus worn on an earlobe, or a fingertip-type apparatus worn at a fingertip.

The electronic apparatus according to the embodiment of the invention is not limited to a biological information acquiring apparatus and may, for example, be an optical communicator or any other electronic apparatus.

### 5. Printer

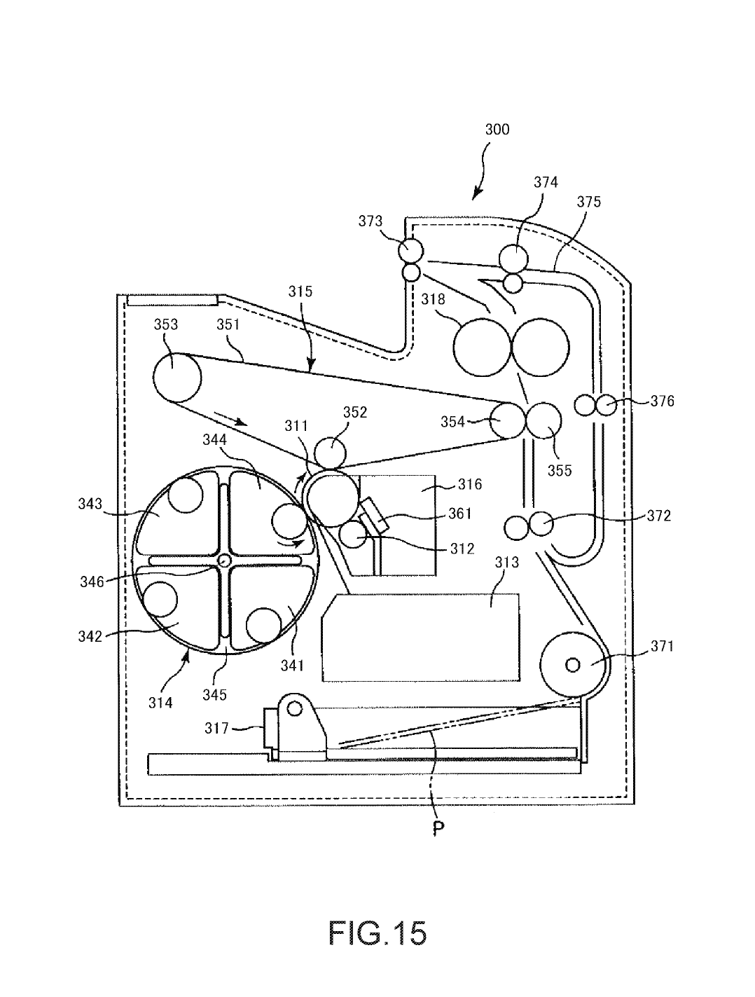

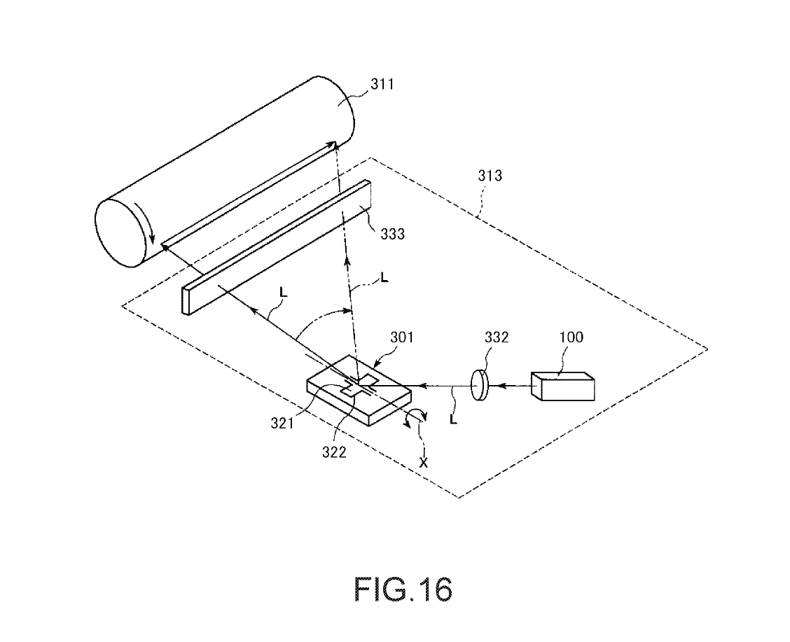

A printer according to the present embodiment will be described with reference to the drawings. FIG. 15 diagrammatically shows a printer (image forming apparatus) 300 according to the present embodiment. FIG. 16 diagrammatically shows a light exposure unit 313 provided in the printer 300 according to the present embodiment.

The printer according to the embodiment of the invention includes one of the vertical cavity surface emitting lasers according to the embodiment of the invention. The following description will be made of the printer 300 including the vertical cavity surface emitting laser 100 described above as one of the vertical cavity surface emitting lasers according to the embodiment of the invention.

The printer 300 records an image made of toner on a recording medium, such as a sheet of paper or an OHP sheet, based on a series of image formation processes including light exposure, development, transfer, and fixation. The printer 300 includes a photosensitive element 311, which rotates in the direction indicated by the arrow associated thereto in FIG. 15, and a charging unit 312, a light exposure unit 313, a development unit 314, a transfer unit 315, and a cleaning unit 316 are sequentially disposed along the direction of rotation of the photosensitive element 311, as shown in FIG. 15. The printer 300 is further provided with a sheet feeding tray 317, which accommodates a recording medium P, such as sheets of paper, in a lower portion of the printer 300 and a fixation apparatus 318 in an upper portion of the printer 300.

In the printer 300, the photosensitive element 311, a development roller (not shown) provided in the development unit 314, and an intermediate transfer belt 351 starts rotating in response to an instruction from a host computer that is not shown. The areas of the rotating photosensitive element 311 are then successively charged by the charging unit 312.

The charged areas of the photosensitive element 311 each reach a light exposure position as the photosensitive element 311 rotates, and the light exposure unit 313 forms a latent image according to information on an image of a first color, for example, yellow Y on the charged area of the photosensitive element 311.

The latent image formed on the photosensitive element 311 reaches a development position as the photosensitive element 311 rotates and is developed by a development apparatus 344 for yellow development by using a yellow toner. A yellow toner image is thus formed on the photosensitive element 311. At this point, in the development unit 314, the development apparatus 344 is so selected as to face the photosensitive element 311 in the development position described above. The selection is performed by rotating a holder 345 around a shaft 346 to change the positions of the development apparatus 341, 342, 343, and 344 with the relative positional relationship among them maintained.

The yellow tone image formed on the photosensitive element 311 reaches a primary transfer position (that is, portion where photosensitive element 311 and primary transfer roller 352 face each other) as the photosensitive element 311 rotates and is transferred by the primary transfer roller 352 onto the intermediate transfer belt 351 (primary transfer). At this point, primary transfer voltage (primary transfer bias) having the polarity opposite the polarity of the charged toner is applied to the primary transfer roller 352. During the voltage application, a secondary transfer roller 355 is separate from the intermediate transfer belt 351.

The same process described above is repeatedly carried out for a second color, a third color, and a fourth color, so that second to fourth color toner images corresponding to image signals are so transferred onto the intermediate transfer belt 351 as to be superimposed on one another. A full-color toner image is thus formed on the intermediate transfer belt 351.

On the other hand, the recording medium P is transported from the sheet feeding tray 317 via a sheet feeding roller 371 and registration rollers 372 to a secondary transfer position (portion where secondary transfer roller 355 and drive roller 354 face each other).

The full-color toner image formed on the intermediate transfer belt 351 reaches the secondary transfer position as the intermediate transfer belt 351 rotates and is transferred by the secondary transfer roller 355 onto the recording medium P (secondary transfer). At this point, the secondary transfer roller 355 is pressed against the intermediate transfer belt 351, and secondary transfer voltage (secondary transfer bias) is applied to the secondary transfer roller 355. The intermediate transfer belt 351 rotates in accordance with rotation of the drive roller 354 while driving and rotating the primary transfer roller 352 and a driven roller 353.

The full-color toner image transferred onto the recording medium P is so heated and pressurized by the fixation apparatus 318 as to be fused onto the recording medium P. Thereafter, in a case of simplex printing, the recording medium P is ejected out of the printer 300 via a pair of sheet ejecting rollers 373.

On the other hand, after the photosensitive element 311 passes the primary transfer position, the toner having adhered to the surface of the photosensitive element 311 is scraped off by a cleaning blade 361 of the cleaning unit 316, and the photosensitive element 311 is now ready to be charged for the following latent image formation. The toner having been scraped off is collected by a residual toner collector in the cleaning unit 316.

In a case of duplex printing, after the recording medium P has undergone the fixation process carried out by the fixation apparatus 318 so that an image has been formed on one side of the recording medium P, and the recording medium P is temporarily sandwiched between the pair of sheet ejecting rollers 373, the pair of sheet ejecting rollers 373 are driven in the reverse direction, and a pair of transport rollers 374 and 376 are so driven that the recording medium P returns to the secondary transfer position along a transport path 375 with the recording medium P upside down. An image is then formed on the other side of the recording medium P by performing the same actions described above.

The light exposure unit 313 provided in the thus configured printer 300 is an apparatus that receives image information from the host computer, such as a personal computer that is not shown, and selectively irradiates the uniformly charged photosensitive element 311 with a laser beam to form an electrostatic latent image.

More specifically, the light exposure unit 313 includes an optical device 301, which is an optical scanner, the vertical cavity surface emitting laser 100, a collimator lens 332, and an fθ lens 333, as shown in FIG. 16.

In the light exposure unit 313, the optical device 301 (light reflector 321) is irradiated with a laser beam L from the vertical cavity surface emitting laser 100 via the collimator lens 332. The laser light L reflected off the light reflector 321 is applied onto the photosensitive element 311 via the fθ lens 333.

In this process, the optical device 301 is driven (caused to pivot around center axis of rotation X of movable plate 322) to scan the photosensitive element 311 in the axial direction thereof with the light (laser beam L) reflected off the light reflector 321. On the other hand, the photosensitive element 311 is scanned in the circumferential direction (sub-scan) with the light (laser beam L) reflected off the light reflector 321 as the photosensitive element 311 rotates. The intensity of the laser beam L emitted from the vertical cavity surface emitting laser 100 changes in accordance with the image information received from the host computer that is not shown.

The light exposure unit 313 thus selectively exposes the photosensitive element 311 with the light for image formation (drawing). The vertical cavity surface emitting laser 100, which can maintain the single mode, for example, even in high-power operation, allows the photosensitive element 311 to be irradiated with the laser beam L in the same pattern (FFP) even when the intensity of the laser beam L changes. That is, grayscale expression of an image dependent on the intensity of the laser beam L can be readily achieved.

The invention encompasses substantially the same configuration as the configuration described in the embodiment (for example, a configuration having the same function, using the same method, and providing the same result or a configuration having the same purpose and providing the same effect). Further, the invention encompasses a configuration in which an inessential portion of the configuration described in the embodiment is replaced. Moreover, the invention encompasses a configuration that provides the same advantageous effects as those provided by the configuration described in the embodiment or a configuration that can achieve the same purpose as that achieved by the configuration described in the embodiment. Further, the invention encompasses a configuration in which a known technology is added to the configuration described in the embodiment.

The entire disclosure of Japanese Patent Application No. 2017-127163 filed Jun. 29, 2017 is expressly incorporated herein by reference.

What is claimed is:

1. A vertical cavity surface emitting laser comprising:
a base; and
a layered element provided on the base,
wherein the layered element includes
a first mirror layer,
a second mirror layer, and
an active layer provided between the first mirror layer and the second mirror layer,
the layered element further includes a light exiting section via which light produced in the active layer exits, and
the light exiting section is an outermost surface of an AlGaInP layer or an AlGaAsP layer.

2. The vertical cavity surface emitting laser according to claim 1,
wherein the first mirror layer is provided between the base and the second mirror layer,
the second mirror layer includes a contact layer connected to an electrode, and
the contact layer is a GaAs layer.

3. The vertical cavity surface emitting laser according to claim 2,
wherein the layered element includes a current narrowing layer that overlaps with the contact layer when viewed in a direction from the first mirror layer to the active layer.

4. The vertical cavity surface emitting laser according to claim 2,
wherein the first mirror layer is provided between the base and the second mirror layer,
the second mirror layer includes
a layered structure element in which a first layer and a second layer having a refractive index smaller than a refractive index of the first layer, the first layer and the second layer being alternately layered on each other, and
a semiconductor layer provided between the layered structure element and a third layer having the outermost surface, and
a bandgap of the third layer is narrower than a bandgap of the semiconductor layer.

5. The vertical cavity surface emitting laser according to claim 4,
wherein the second mirror layer includes a graded index layer provided between the layered structure element and the semiconductor layer, composition of the graded index layer gradually changes in a direction from the layered structure element toward the semiconductor layer,
a sum of half of an optical path length of the graded index layer, an optical path length of the semiconductor layer, and an optical path length of the third layer is an odd number times of λ/4, where λ is a wavelength of the light produced in the active layer, and
an optical path length of the contact layer is an odd number times of λ/4.

6. The vertical cavity surface emitting laser according to claim 1,
wherein the light exiting section is an outermost surface of the AlGaInP layer,
a composition of the AlGaInP layer is represented as a formula (AlₓGa₁₋ₓ)_{1-y}In_{y}P, the x and the y satisfy y≥0.34x+0.36, 0≤x<1 and y<1.

7. The vertical cavity surface emitting laser according to claim 6,
wherein the x and the y satisfy y≤0.33x+0.42 and y≤0.61.

8. The vertical cavity surface emitting laser according to claim 1,
wherein the light exiting section is an outermost surface of the AlGaAsP layer,
a composition of the AlGaAsP layer is represented as a formula (Alₓ Ga₁₋ₓ)_{1-y}As_{y}P, the x and they satisfy y≤−3.90x+1.95, 0<x<1 and 0≤y≤0.39.

9. The vertical cavity surface emitting laser according to claim 8,
wherein the x and the y satisfy y≥−1.39x+0.39.

10. A method for manufacturing a vertical cavity surface emitting laser, the method comprising:
forming a first mirror layer, an active layer, and a second mirror layer including an AlGaInP layer or an AlGaAsP layer and a contact layer in an order of the first mirror layer, the active layer, and the second mirror layer on a base to form a layered element;
forming an electrode connected to the contact layer; and
patterning the contact layer after the formation of the electrode in such a way that the AlGaInP layer or the AlGaAsP layer is exposed,
wherein the layered element includes a light exiting section via which light produced in the active layer exits, and
the light exiting section is an outermost surface of the AlGaInP layer or the AlGaAsP layer.

11. An electronic apparatus comprising the vertical cavity surface emitting laser according to claim 1.

12. An electronic apparatus comprising the vertical cavity surface emitting laser according to claim 2.

13. An electronic apparatus comprising the vertical cavity surface emitting laser according to claim 3.

14. An electronic apparatus comprising the vertical cavity surface emitting laser according to claim 4.

15. An electronic apparatus comprising the vertical cavity surface emitting laser according to claim 5.

16. A printer comprising the vertical cavity surface emitting laser according to claim 1.

17. A printer comprising the vertical cavity surface emitting laser according to claim 2.

18. A printer comprising the vertical cavity surface emitting laser according to claim 3.

19. A printer comprising the vertical cavity surface emitting laser according to claim 4.

20. A printer comprising the vertical cavity surface emitting laser according to claim 5.
